(19) United States
(12) Patent Application Publication
(10) Pub. No.: US 2025/0316581 A1
(43) Pub. Date: Oct. 9, 2025

(54) FLOATING NODE IN AN INTEGRATED CIRCUIT

(71) Applicant: International Business Machines Corporation, Armonk, NY (US)

(72) Inventors: Rajiv Joshi, Yorktown Heights, NY (US); Ruilong Xie, Niskayuna, NY (US)

(21) Appl. No.: 18/629,400

(22) Filed: Apr. 8, 2024

(51) Int. Cl. H01L 23/522; H01L 23/528; H10B 12/00

(52) U.S. Cl. CPC H01L 23/5226; H01L 23/528; H10B 12/09; H10B 12/20; H10B 12/50

(57) ABSTRACT

A semiconductor structure includes a device layer including a device region with a plurality of devices and a pre-charging circuit; a front side wiring layer, located on a front side of the device layer, and including at least signal wiring connected to the device region; a supply voltage line coupled to the device region; and a back side wiring layer, located on a back side of the device layer. The back side wiring layer includes a virtual power rail coupled to the pre-charging circuit and a transient line capacitively but not conductively coupled to the virtual power rail and coupled to the device region. The pre-charging circuit is configured to cause the virtual power rail to experience a voltage differential from a supply voltage applied to the supply voltage line responsive to a pulse on the transient line.

### BACKGROUND

The present technology relates to the electrical, electronic, and computer arts, and more specifically, to virtual functionality (e.g., floating nodes) for integrated circuits such as memory circuits and the like.

Virtual functionality at lower voltages is significant for circuits such as memory circuits; use of a virtual node is a pertinent aspect for lowering the required supply voltage for memories. When a virtual node is formed on the front side of the wafer, i.e., using continued buildup on the back end of the line (BEOL) with multiple wiring layers such as M1, M2, M3, M4, M5, and so on, BEOL congestion is increased (since there are too many wires present). Furthermore, the voltage boost that can be achieved by a virtual node is limited by the capacitance between the virtual node and the transient line to which it is capacitively coupled.

### SUMMARY

Principles of the technology provide techniques for a floating node in an integrated circuit. In one aspect, an exemplary semiconductor structure includes a device layer including a device region with a plurality of devices and a pre-charging circuit; a front side wiring layer, located on a front side of the device layer, and including at least signal wiring connected to the device region; a supply voltage line coupled to the device region; and a back side wiring layer, located on a back side of the device layer. The back side wiring layer includes a virtual power rail coupled to the pre-charging circuit and a transient line capacitively but not conductively coupled to the virtual power rail and coupled to the device region. The pre-charging circuit is configured to cause the virtual power rail to experience a voltage differential from a supply voltage applied to the supply voltage line responsive to a pulse on the transient line.

In another aspect, another exemplary semiconductor structure includes a device layer including a device region with a plurality of devices and a pre-charging circuit; a supply voltage line coupled to the device region; and a wiring layer, located adjacent the device layer. The wiring layer includes a virtual power rail coupled to the pre-charging circuit and a transient line capacitively but not conductively coupled to the virtual power rail and coupled to the device region. The pre-charging circuit is configured to cause the virtual power rail to experience a voltage differential from a supply voltage applied to the supply voltage line responsive to a pulse on the transient line. The virtual power rail and the transient line are formed with interdigitated conductive teeth separated by a dielectric.

In still another aspect, an exemplary method of forming a semiconductor structure includes providing an initial structure including a carrier wafer, a plurality of front side wiring layers outward of the carrier wafer, and a device layer outward of the plurality of front side wiring layers, the device layer including a device region and a pre-charging circuit; forming a back side transient power line on a back side of the device region, the back side transient power line including wiring in a first metal region with first via bumps extending therefrom; and forming a back side virtual power rail on the back side of the device region. The back side virtual power rail includes wiring in a second metal region that is spaced vertically from the first metal region, and the back side virtual power rail further includes second via bumps extending from it. The first via bumps and the second via bumps extend towards each other and are interdigitated and separated from each other by back side inter layer dielectric. The back side virtual power rail is coupled to the pre-charging circuit.

In a further aspect, still another exemplary semiconductor structure includes a device layer including a device region with a plurality of devices and a pre-discharging circuit; a front side wiring layer, located on a front side of the device layer, and including at least signal wiring connected to the device region; and a back side wiring layer, located on a back side of the device layer. The back side wiring layer includes a virtual power rail coupled to the pre-discharging circuit, and a transient line capacitively but not conductively coupled to the virtual power rail and coupled to the device region. The pre-discharging circuit is configured to cause the virtual power rail to experience a voltage differential from an initial ground potential responsive to a pulse on the transient line.

In yet a further aspect, yet another exemplary semiconductor structure includes a device layer including a device region with a plurality of devices and a pre-discharging circuit; and a wiring layer, located adjacent the device layer. The wiring layer includes a virtual power rail coupled to the pre-discharging circuit, and a transient line capacitively but not conductively coupled to the virtual power rail and coupled to the device region. The pre-discharging circuit is configured to cause the virtual power rail to experience a voltage differential from an initial ground potential responsive to a pulse on the transient line, and the virtual power rail and the transient line are formed with interdigitated conductive teeth separated by a dielectric.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts an exemplary structure, according to an aspect of the invention.

FIG. 2 depicts a first exemplary pre-charge circuit (positive boost virtual line), according to an aspect of the invention.

FIG. 3 depicts a second type of pre-charge circuit (positive boost virtual line), according to an aspect of the invention.

FIG. 4 depicts timing diagram with waveforms, according to an aspect of the invention.

FIGS. 5-13 depict steps in a first exemplary fabrication method, according to an aspect of the invention.

FIGS. 14-26 depict steps in a second exemplary fabrication method, according to an aspect of the invention.

FIG. 27 depicts a computing environment according to an embodiment of the present invention.

FIG. 28 is a flow diagram of a design process used in semiconductor design, manufacture.

FIG. 29 depicts a pre-discharge circuit (negative boost virtual line), according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of technology described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure includes a device layer 1407 including a device region 508Z with a plurality of devices and a pre-charging circuit (element 301Z, for example). Also included are a front side wiring layer (lower BEOL layers 1408), (more BEOL layers 1411), located on a front side of the device layer, and including at least signal wiring connected to the device region; and a supply voltage line coupled to the device region (represented by any of the metal other than the virtual power rail and transient line). A back side wiring layer is located on a back side of the device layer and includes a virtual power rail 1425 coupled to the pre-charging circuit (note that as will be appreciated by the skilled artisan from the context, except for the capacitive coupling between elements 1425 and 1419A, coupling generally means conductive coupling). A transient line 1419A is capacitively but not conductively coupled to the virtual power rail and is coupled to the device region. The pre-charging circuit is configured to cause the virtual power rail to experience a voltage differential from a supply voltage applied to the supply voltage line responsive to a pulse on the transient line. Technical advantages include achieving functionality of logic/memory at low voltage by using coupling capacitance to form a floating node. Formation in the backside provides area savings for increased density. One or more embodiments overcome the need for a separate voltage supply/voltage regulator/voltage converter; for example, providing a positive or negative voltage boost to the bit lines in a memory array where the device region includes a memory array.

Referring to the vias extending from elements 1419A and 1425 with BILD in between, in one or more embodiments, the virtual power rail and the transient line are formed with interdigitated conductive teeth separated by a dielectric. Technical advantages include enhancing coupling capacitance by forming interdigitated vias between a virtual power rail and a transient supply line.

In some cases, the virtual power rail and the transient line are vertically spaced from each other and the interdigitated conductive teeth are vertical vias. Technical advantages include enhancing coupling capacitance by forming interdigitated vias between a virtual power rail and a transient supply line with a structure that is readily manufactured.

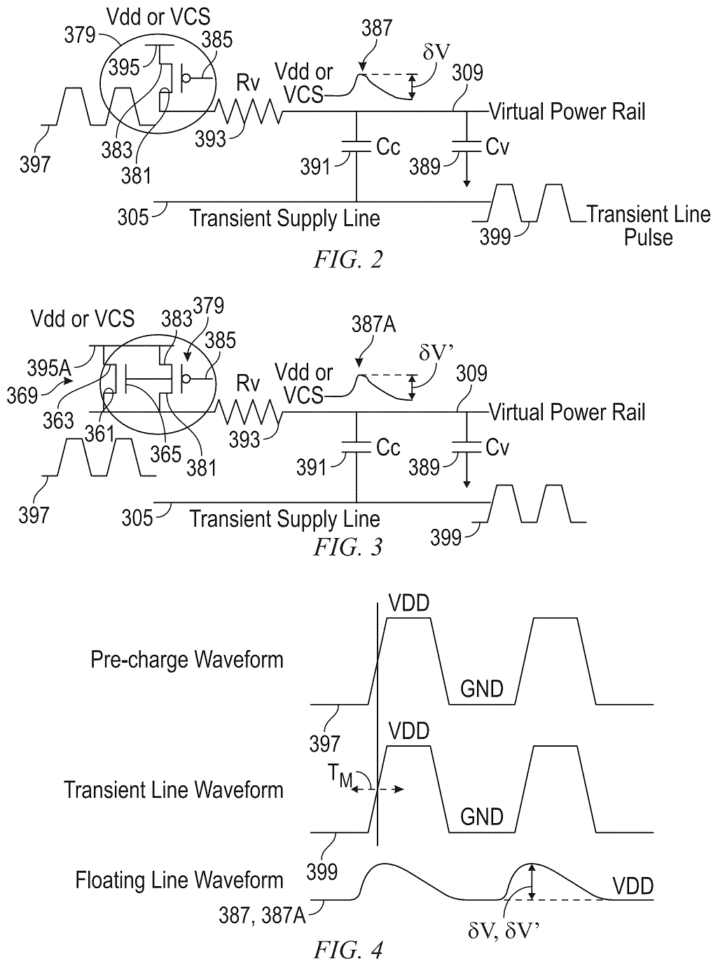

Referring to FIG. 2, in some cases, the pre-charging circuit includes a p-type field effect transistor having a first drain-source terminal coupled to the supply voltage line, a gate, and a second drain-source terminal coupled to the virtual power rail. Technical advantages include a pre-charging circuit that is readily manufactured and suitable for a wide range of operating frequencies.

At least some such cases further include a controller and power supply 303 configured to supply input pulse waveforms to the transient supply line and the gate of the p-type field effect transistor. Technical advantages include controlling operation of the circuit to achieve indicated benefits.

In some cases, the input pulse waveforms are in phase and the voltage differential is positive. Technical advantages include providing a positive voltage boost for circuits where that is helpful.

On the other hand, in some cases, the input pulse waveforms are out of phase and the voltage differential is negative. Technical advantages include providing a negative voltage “tweak” for circuits where that is helpful.

Referring to FIG. 3, in some cases, the pre-charging circuit includes a p-type field effect transistor having a first drain-source terminal coupled to the supply voltage line, a gate, and a second drain-source terminal coupled to the virtual power rail; and an n-type field effect transistor having a first drain-source terminal coupled to the first drain-source terminal of the p-type field effect transistor, a gate coupled to the gate of the p-type field effect transistor, and a second drain-source terminal coupled to the second drain-source terminal of the p-type field effect transistor. Technical advantages include a pre-charging circuit that is readily manufactured and provides a higher boost but may be preferable for higher frequency/shorter period circuits.

At least some such cases further include a controller and power supply configured to supply input pulse waveforms to the transient supply line and the gates of the p-type field effect transistor and the n-type field effect transistor. Technical advantages include controlling operation of the circuit to achieve indicated benefits.

In some cases, the input pulse waveforms are in phase and the voltage differential is positive. Technical advantages include providing a positive voltage boost for circuits where that is helpful.

On the other hand, in some cases, the input pulse waveforms are out of phase and the voltage differential is negative. Technical advantages include providing a negative voltage “tweak” for circuits where that is helpful.

In another aspect, another exemplary semiconductor structure includes a device layer including dielectric 509, a device region 508 with a plurality of devices and a pre-charging circuit (element 301 is generally representative of a pre-charging circuit and a pre-discharging circuit). A supply voltage line is coupled to the device region (represented by any of the metal other than the virtual power rail and transient line). A wiring layer is located adjacent to the device layer, and includes a virtual power rail 585 coupled to the pre-charging circuit and a transient line (e.g., M2 with teeth 589) capacitively but not conductively coupled to the virtual power rail and coupled to the device region. The pre-charging circuit is configured to cause the virtual power rail to experience a voltage differential from a supply voltage applied to the supply voltage line responsive to a pulse on the transient line, and the virtual power rail and the transient line are formed with interdigitated conductive teeth separated by a dielectric (teeth of 585 and teeth 589 separated by ILD 595B). Technical advantages include achieving functionality of logic/memory at low voltage by using coupling capacitance to form a floating node; overcoming the need for separate voltage supply/voltage regulator/voltage converter; providing a positive or negative voltage boost to the bit lines in a memory array where the device region includes a memory array; and enhancing coupling capacitance by forming interdigitated vias between a virtual power rail and a transient supply line.

In some instances, the virtual power rail and the transient line are vertically spaced from each other and the interdigitated conductive teeth include vertical vias. Technical advantages include enhancing coupling capacitance by forming interdigitated vias between a virtual power rail and a transient supply line with a structure that is readily manufactured.

Referring to FIG. 2, in some cases, the pre-charging circuit includes a p-type field effect transistor having a first drain-source terminal coupled to the supply voltage line, a gate, and a second drain-source terminal coupled to the virtual power rail. Technical advantages include a pre-charging circuit that is readily manufactured and suitable for a wide range of operating frequencies.

Some such cases further include a controller and power supply 303 configured to supply input pulse waveforms to the transient supply line and the gate of the p-type field effect transistor. Technical advantages include controlling operation of the circuit to achieve indicated benefits.

In some such cases, the input pulse waveforms are in phase and the voltage differential is positive. Technical advantages include providing a positive voltage boost for circuits where that is helpful.

On the other hand, in other such cases, the input pulse waveforms are out of phase and the voltage differential is negative. Technical advantages include providing a negative voltage “tweak” for circuits where that is helpful.

Referring to FIG. 3, in some cases, the pre-charging circuit includes a p-type field effect transistor having a first drain-source terminal coupled to the supply voltage line, a gate, and a second drain-source terminal coupled to the virtual power rail; and an n-type field effect transistor having a first drain-source terminal coupled to the first drain-source terminal of the p-type field effect transistor, a gate coupled to the gate of the p-type field effect transistor, and a second drain-source terminal coupled to the second drain-source terminal of the p-type field effect transistor. Technical advantages include a pre-charging circuit that is readily manufactured and provides a higher boost but may be preferable for higher frequency/shorter period circuits.

Some such cases further include a controller and power supply 303 configured to supply input pulse waveforms to the transient supply line and the gates of the p-type field effect transistor and the n-type field effect transistor. Technical advantages include controlling operation of the circuit to achieve indicated benefits.

In some such cases, the input pulse waveforms are in phase and the voltage differential is positive or the input pulse waveforms are out of phase and the voltage differential is negative. Technical advantages include providing a positive voltage boost for circuits where that is helpful, or providing a negative voltage “tweak” for circuits where that is helpful, as the case may be.

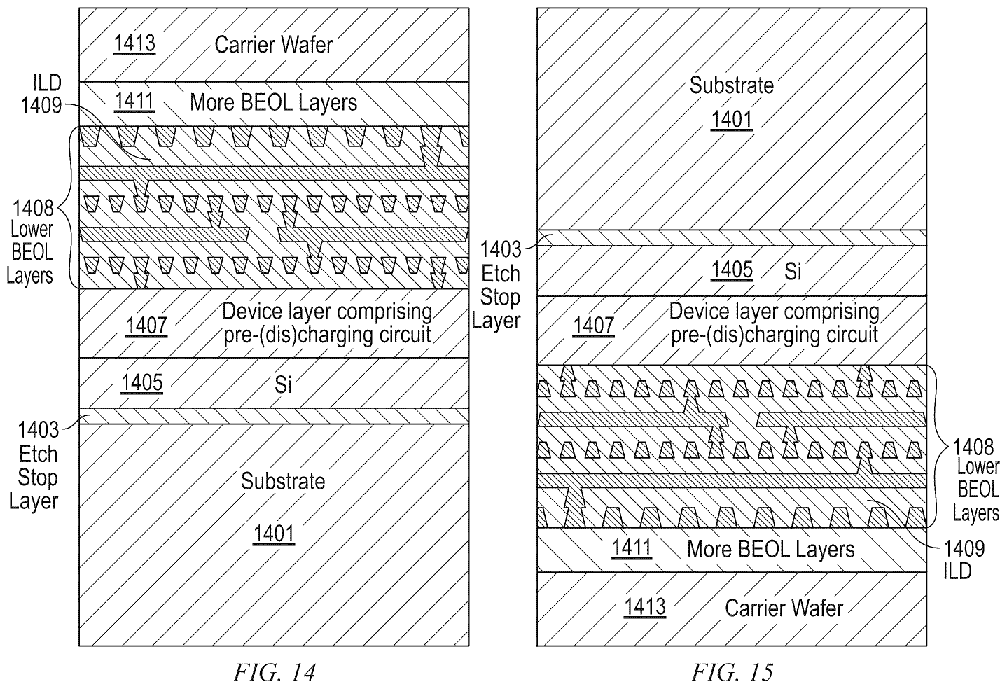

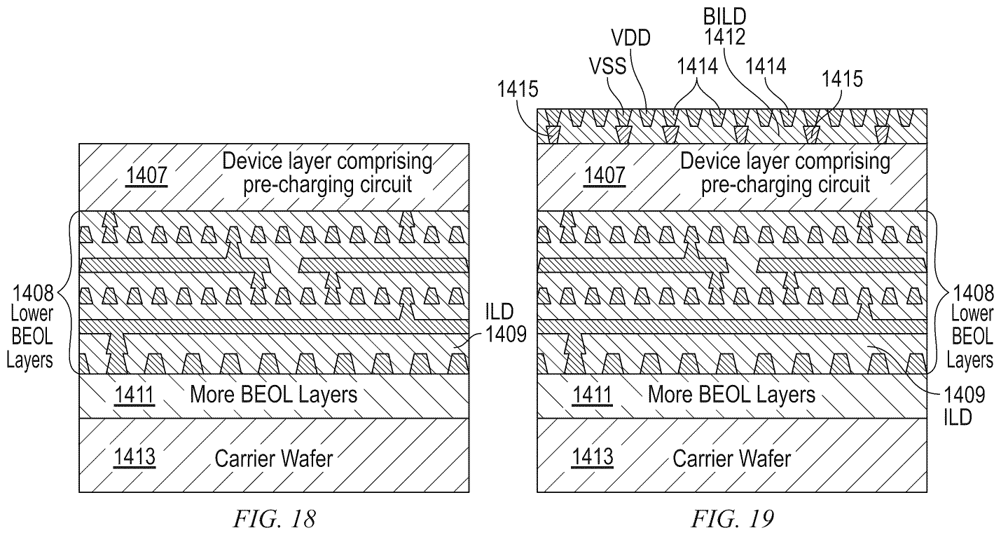

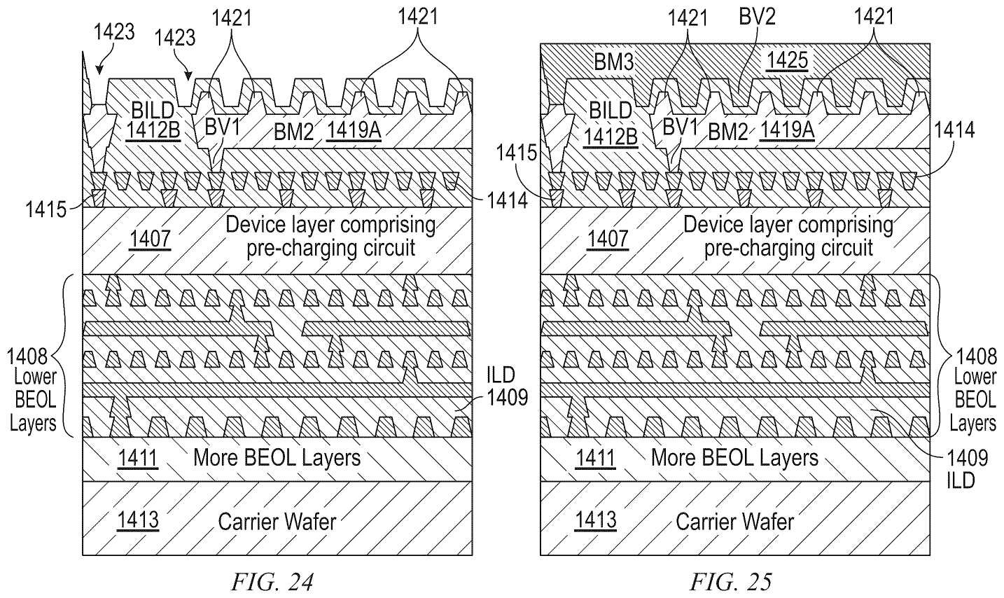

In still another aspect, referring to FIGS. 14-26, consider an exemplary method of forming a semiconductor structure. Referring to FIG. 18, provide an initial structure including a carrier wafer, a plurality of front side wiring layers outward of the carrier wafer, and a device layer outward of the plurality of front side wiring layers, the device layer including a device region and a pre-charging circuit. A further step, with reference to FIGS. 19-23, includes forming a back side transient power line on a back side of the device region. The back side transient power line includes wiring in a first metal region with first via bumps extending from it. A still further step, with reference to FIGS. 24-26, includes forming a back side virtual power rail on the back side of the device region. The back side virtual power rail includes wiring in a second metal region that is spaced vertically from the first metal region. The back side virtual power rail further includes second via bumps extending from it. The first via bumps and the second via bumps extend towards each other and are interdigitated and separated from each other by back side inter layer dielectric. The back side virtual power rail is coupled to the pre-charging circuit. Technical advantages include techniques that provide a structure with the advantages discussed above.

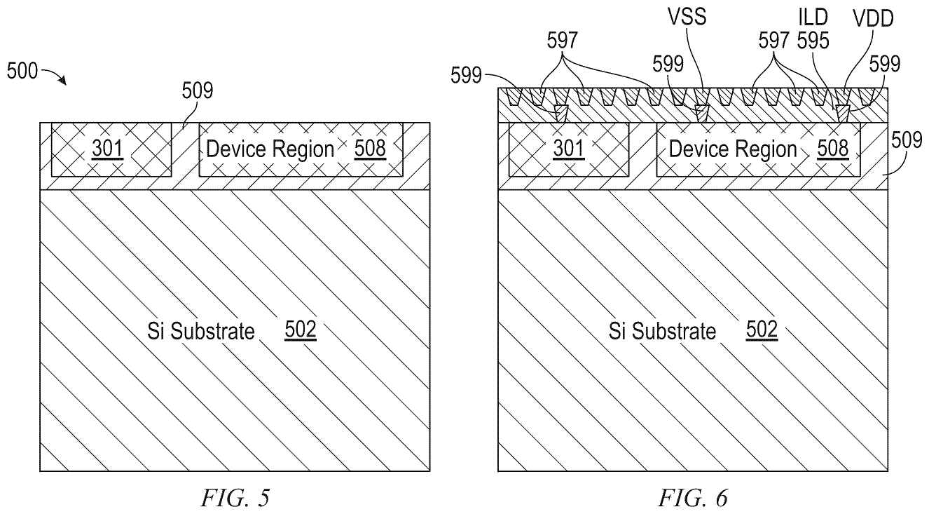

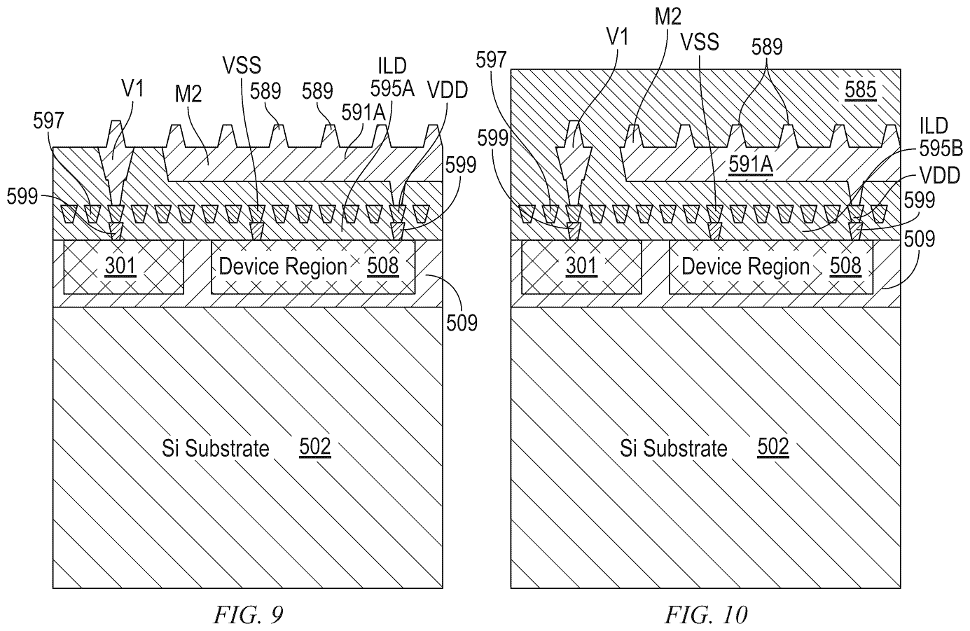

In a further aspect, referring to FIGS. 5-13, consider another exemplary method of forming a semiconductor structure. Referring to FIG. 5, provide an initial structure including a substrate and a device layer outward of the substrate. The device layer includes a device region and a pre-charging circuit. A further step, referring to FIGS. 6-8, includes forming middle of line contacts and back end of line wiring outward of the device layer. The back end of line wiring includes a transient power line connected to the device region by at least one of the middle of line contacts. A still further step includes forming first via bumps extending from the transient power line, as in FIG. 9. Referring to FIGS. 10-13, yet a further step includes forming a virtual power rail spaced vertically from the transient power line. The virtual power rail includes second via bumps extending from it, and the first via bumps and the second via bumps extend towards each other and are interdigitated and separated from each other by inter layer dielectric. The virtual power rail is coupled to the pre-charging circuit. Technical advantages include techniques that provide a structure with the advantages discussed above.

In yet a further aspect, a method of operating a circuit, generally applicable to embodiments disclosed herein, includes providing a semiconductor structure. The semiconductor structure includes a device layer including a device region with a plurality of devices and a pre-charging circuit; a supply voltage line coupled to the device region; and a wiring layer, located adjacent the device layer. The wiring layer includes a virtual power rail coupled to the pre-charging circuit and a transient line capacitively but not conductively coupled to the virtual power rail and coupled to the device region. Further steps include applying a supply voltage to the supply voltage line; applying a pulse to the transient line; and, using the pre-charging circuit, causing the virtual power rail to experience a voltage differential from the supply voltage applied to the supply voltage line responsive to the pulse on the transient line. Technical advantages include achieving functionality of logic/memory at low voltage by using coupling capacitance to form a floating node.

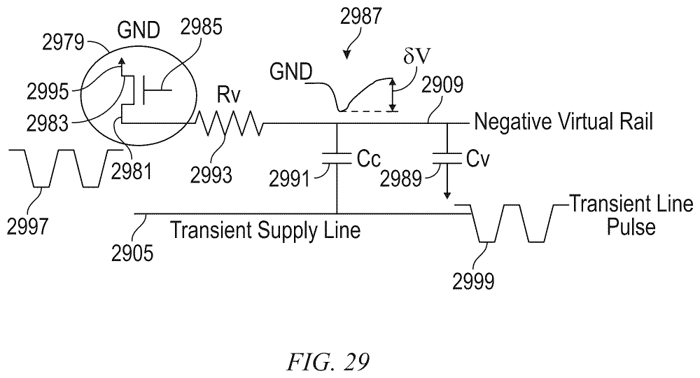

In an additional aspect, referring to FIG. 29, still another semiconductor structure includes a device layer including a device region with a plurality of devices and a pre-discharging circuit; a front side wiring layer, located on a front side of the device layer, and including at least signal wiring connected to the device region; and a back side wiring layer, located on a back side of the device layer. The back side wiring layer includes a virtual power rail coupled to the pre-discharging circuit, and a transient line capacitively but not conductively coupled to the virtual power rail and coupled to the device region. The pre-discharging circuit is configured to cause the virtual power rail to experience a voltage differential from an initial ground potential responsive to a pulse on the transient line. Technical benefits are generally similar to those discussed above for positive boost virtual lines, for cases where negative boost virtual lines are appropriate.

In some instances, the virtual power rail and the transient line are formed with interdigitated conductive teeth separated by a dielectric. Technical advantages include enhancing coupling capacitance in a manner generally similar to that discussed above.

In another additional aspect, referring to FIG. 29, yet another semiconductor structure includes a device layer including a device region with a plurality of devices and a pre-discharging circuit; and a wiring layer, located adjacent the device layer, and including: a virtual power rail coupled to the pre-discharging circuit; and a transient line capacitively but not conductively coupled to the virtual power rail and coupled to the device region. The pre-discharging circuit is configured to cause the virtual power rail to experience a voltage differential from an initial ground potential responsive to a pulse on the transient line, and the virtual power rail and the transient line are formed with interdigitated conductive teeth separated by a dielectric. Technical benefits are generally similar to those discussed above for positive boost virtual lines, for cases where negative boost virtual lines are appropriate.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:

Achieving functionality of logic/memory at low voltage by using coupling capacitance to form a floating node.

Enhancing coupling capacitance by forming interdigitated vias between a virtual power rail and a transient supply line.

Achieving functionality of logic/memory at low supply voltage by usage of coupling capacitors.

Usage of vias in the backside provides area savings for increased density.

As noted, virtual functionality at lower voltages is significant for circuits such as memory circuits; use of a virtual node is a pertinent aspect for lowering the required supply voltage for memories. In one or more embodiments, the concept of a virtual node uses the spacing between two metal structures (e.g., horizontal lines and/or vertical vias), to achieve capacitive coupling.

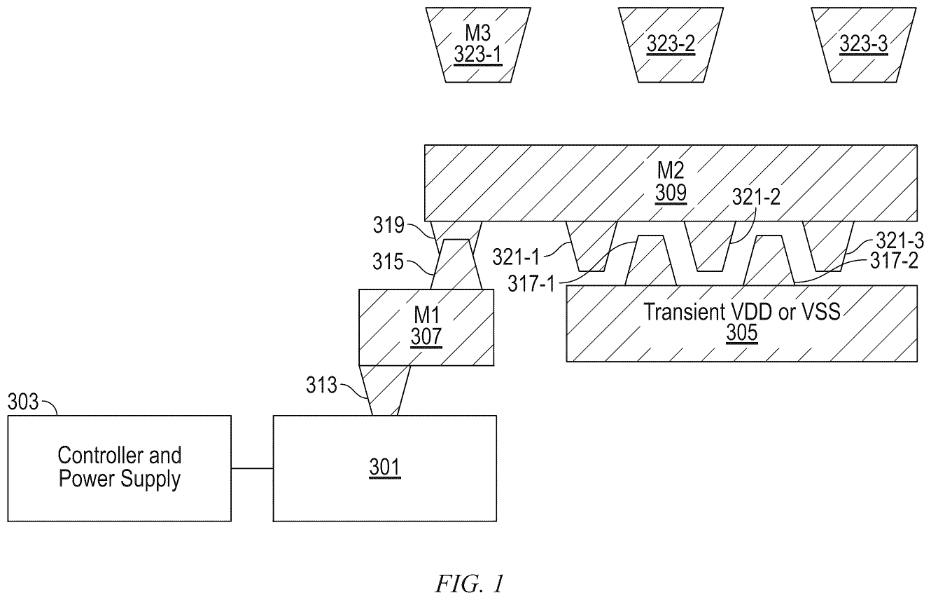

FIG. 1 depicts an exemplary structure, according to an aspect of the invention. Note the pre-charging circuit (represented by element 301) controlled by a suitable controller (depicted for illustrative convenience as part of combined controller and power supply 303 but separate controller and power (e.g., voltage) supply circuits can also be used); elements 301 and 303 are both discussed further below. Note also the virtual power rail 309. In the non-limiting example of FIG. 1, the virtual power rail 309 is formed in metal layer M2 (can be backside as per FIGS. 14-26 or front side as per FIGS. 5-13). Transient line 305 can be toggled from VDD to ground or ground to VDD. The pre-charging circuit and controller and power supply 303 are depicted schematically in FIG. 1. The pre-charging circuit is coupled to virtual power rail 309 by via 313, metal line 307 at the M1 layer, via 315, and via 319. Virtual power rail 309 and transient line 305 are capacitively coupled by vias 317-1, 317-2 that are conductively coupled to transient line 305 and vias 321-1, 321-2, 321-3 that are conductively coupled to virtual power rail 309. The vias 317-1, 317-2 and 321-1, 321-2, 321-3 are interdigitated with each other. They are separated by a dielectric (such as ILD or BILD discussed and illustrated below)) so that they are capacitively coupled but not conductively coupled. An additional metal layer M3 with lines 323-1, 323-2, 323-3 running perpendicular to the page is also shown, it being understood that there can be many additional layers of wiring and vias and that the virtual power rail 309 and transient line 305 can be formed at different metal layers than in the example of FIG. 1.

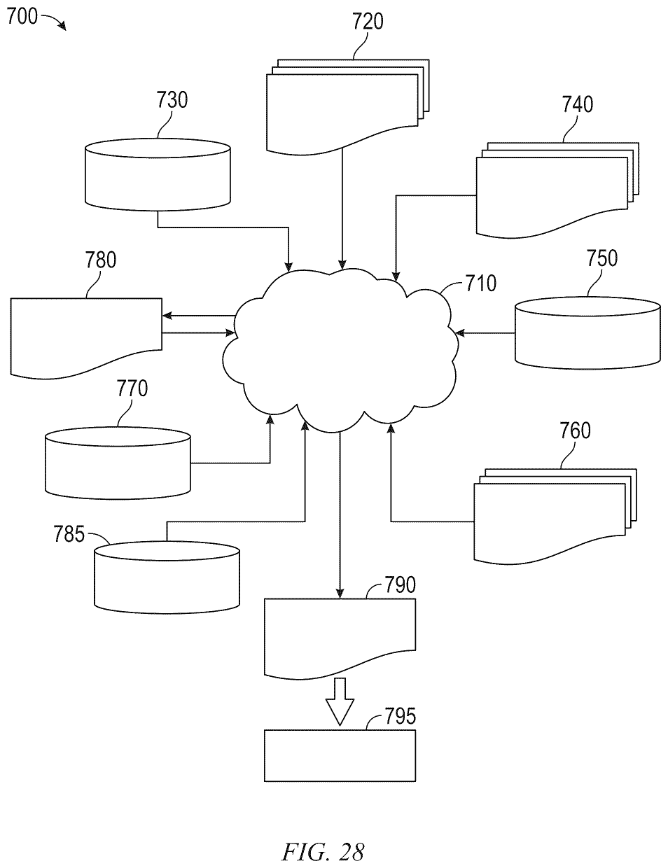

The controller of controller and power supply 303 carries out functions as defined herein; given the teachings and description of the functions herein, known power/voltage supplies and known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry as described below with respect to FIG. 28.

It will be appreciated that the capacitive coupling of the virtual power rail 309 and transient line 305 is enhanced by providing the interdigitated vias, e.g., in a saw-tooth fashion. In a non-limiting example, vias 321-1, 321-2, 321-3 are unlanded damascene vias and vias 317-1, 317-2 are unlanded subtractive vias.

FIG. 2 depicts a first exemplary pre-charging circuit, according to an aspect of the invention. This first exemplary pre-charging circuit includes a p-type field effect transistor (PFET) 379 that has a first source-drain terminal 383 connected to a fixed-voltage power supply rail 395 at Vdd or VCS. The gate 385 of the PFET 379 is provided with an input waveform 397. A second source-drain terminal 381 is connected to virtual power rail 309 through resistance Rv 393. The virtual power rail 309 is capacitively coupled to the transient supply line 305 through capacitance Cc 391, and in the example of FIG. 2, is coupled to ground through capacitance Cv 389. Transient supply line 305 has an applied waveform 399. Using a suitable controller and power supply, the transistor is turned ON by a signal on its gate when it is desired to supply power to the line by capacitive coupling.

In this context, “coupling” between line 305 and rail 309 means that when the transient supply line voltage goes up (transient supply line 305 has an applied voltage which is fluctuating low-high-low-high . . . as seen at 399), then the virtual power rail 309 will “glitch” up. This means that the virtual power rail 309 will go higher than the initialized voltage (say, Vdd). This is desirable, because without applying any higher voltage than Vdd, a voltage higher than Vdd can be dynamically generated, using the coupling between the rail 309 and line 305. Stated another way, because of the capacitance between the rail 309 and line 305, it is possible to “jack up” the virtual power rail 309.

Placing the rail 309 and line 305 on the front side of the wafer requires signal lines, virtual lines, coupling lines, and the like all at one side, thus resulting in congestion, and limiting density. Advantageously, one or more embodiments overcome these limitations through the use of buried signal lines on the back side; i.e., back side power and signal delivery to the floating lines.

Still with reference to FIG. 2, when the input signal (input waveform 397) on the gate 385 of the PFET 379 is zero, the PFET is ON, and it initializes the virtual power rail 309 to high (i.e., Vdd or VCS; Vdd is the digital supply voltage and VCS is the cell supply). Whatever voltage is applied on the first source-drain terminal 383 of the PFET 379 will show up on the virtual power rail 309. Then, the PFET 379 is turned OFF by applying a HIGH to its gate 385. In the example of FIG. 2, the same signal (applied waveform 399) as is applied to the transient supply line 305 is applied to the gate 385 of the PFET 379, as seen at 397 (i.e., similar polarity). When the signal on the gate 385 goes high, the PFET is shut off. The charge on the virtual power rail 309 remains and it “floats” at Vdd or VCS as the case may be. When the voltage (applied waveform 399) on the transient supply line 305 goes from low to high, because of the capacitance Cc 391, the virtual power rail 309 “glitches” up as seen in the small plot 387. There is a “boost” or “glitch” to the upper line above Vdd or VCS, in the amount of SV. In one or more embodiments the δV is on the order of 0.1-0.2 V.

It is worth noting that the polarity of the transient supply line pulse (applied waveform 399) could alternatively be 180 degrees out of phase with the pulse (input waveform 397) on the gate 385 of the PFET 379, such that instead of both waveforms starting with a low (0 voltage, logical zero) and going high (Vdd or VCS, logical one), applied waveform 399 starts with a high and goes low. In such a case, the virtual power rail 309 will glitch down instead of up. That is to say, when the input waveform 397 to the PFET and the transient line pulse (applied waveform 399) are in phase, a positive glitch +δV is obtained, while when they are 180 degrees out of phase, a negative glitch −δV is obtained. Stated another way, in the example depicted in FIG. 2, the two sawtooth waves are in phase and provide a positive glitch/boost; if they were 180 degrees out of phase, a negative glitch/boost would be obtained. Stated in still another way, the transient supply line 305 pushes up virtual power rail 309 through Cc if the signals are in phase, but pulls down virtual power rail 309 through Cc if the signals are out of phase.

Cc 391 is thus the capacitance between the rail 309 and line 305 with the dielectric, such as ILD or BILD discussed below, in between. Generally, the determination of this capacitance is complex as the geometry is not simply that of a parallel plate capacitor, including both vertical and horizontal elements. Given the teachings herein, however, the skilled person can determine the capacitance between the rail 309 and line 305 (for example, using finite element techniques). In one or more embodiments, the vias 321-1, 321-2, 321-3 coupled to the virtual power rail 309 are offset from the vias 317-1, 317-2 coupled to the transient line 305, to adjust the Cc. Any of the vias can be convention vias shaped like a coffee cup (truncated cone) or could also be lines or slot vias (like a member with a rectangular cross section and extending into the plane of the paper). The rail 309 with vias 321-1, 321-2, 321-3 and the line 305 with vias 317-1, 317-2 thus form two plates of a capacitor with capacitance value Cc. The value of Cc will depend on the horizontal gap between the teeth and the vertical gap between the ends of the teeth and the opposite lines. Many interdigitated vias can be provided. The virtual rail 309 could optionally extend further into M3, M4, . . . , and similarly with the transient line 305.

One or more embodiments advantageously (i) form inventive structures from the back side to reduce congestion and increase density and/or (ii) increase capacitance Cc, and thus increase dynamic boost δV, by enhancing capacitance with interdigitated vias.

FIG. 3 depicts a second exemplary pre-charging circuit, according to an aspect of the invention; elements similar to those in FIG. 2 have received the same number and are not described again except to the extent needed to describe construction and operation of the example in FIG. 3. The voltage glitch here is designated as δV′ and the small plot as 387A. The fixed-voltage power supply rail at Vdd or VCS is here designated as 395A. There is an n-type FET (NFET) 369 that is connected in parallel with the PFET 379 between rail 395 and the resistance 393 (resistance 393 is the wire resistance of that virtual power rail (as shown in the figure)). NFET 369 has first source-drain terminal 363 coupled to rail 395A, second source-drain terminal 361 connected to rail 309 through resistance 393, and gate 365 coupled to gate 385 of PFET 379.

The skilled artisan will of course recall that the NFET turns ON when the gate-source voltage Vgs exceeds the threshold voltage, while the PFET turns ON when the gate-source voltage Vgs is less than the threshold voltage. When the virtual power rail sawtooth waveform (input waveform 397) applied to the PFET and NFET gates is LOW, the PFET is thus ON and the NFET is OFF. The virtual power rail 309 is charged to Vdd or VCS as the case may be. When the virtual power rail sawtooth (input waveform 397) goes HIGH, the PFET will shut off, and the gate of the NFET will be sitting at Vdd or VCS as the case may be. The first drain-source terminal 363 of the NFET, in this case functioning as a drain, is also at Vdd and the second drain-source terminal 361 of the NFET, in this case functioning as a source, is also at Vdd; thus, Vgs for the NFET is zero. At this point, the NFET 369 only acts as a capacitor and pulls the virtual power rail 309 even further up than in the first embodiment, acting in addition to the action of the transient supply line 305 through Cc. Consider operation at relatively slow speeds such as 10 MHz. The period of the sawtooth will increase accordingly compared to a faster circuit (say 50 MHz), and the circuit will start leaking charge. While the PFET 379 is shut off, the NFET 369 will eventually turn on and the virtual power rail 309 will reach Vdd or VCS less Vt, meaning that the charge will not be depleted from that line and it will not go to zero, but it will not stay at the “boosted” value. The embodiment of FIG. 3 thus provides a higher boost than the embodiments of FIG. 2, but due to the leakage issue, may be preferable for higher frequency/shorter period circuits as compared to that of FIG. 2.

FIGS. 2 and 3 have presented exemplary positive dynamic virtual lines. Referring to FIG. 29, note that, in another aspect, by changing the PFET 379 in FIG. 2 to an NFET 2979 in FIG. 29, and connected to ground (GND) 2995 and to a virtual line 2909, the virtual line 2909 can be initialized to GND and later floated by turning the NFET 2979 OFF. Changing the voltage of the transient line 2905 from a high to low, a negative value on the virtual line can be obtained due to capacitive coupling. In short, both techniques (negative and positive boosts) can advantageously be achieved through back side virtual power delivery in accordance with aspect of the invention. Except as discussed in this paragraph, elements 2905, 2909, 2999, 2997, 2995, 2993, 2991, 2989, 2987, 2985, 2983, 2981, 2979 are otherwise analogous to the respective corresponding elements 305, 309, 399, 397, 395, 393, 391, 389, 387, 385, 383, 381, 379 in FIG. 2. The skilled artisan will of course appreciate that the NFET turns ON when the gate-source voltage Vgs exceeds the threshold voltage Vt while the PFET turns ON when the gate-source voltage Vgs is less than the threshold voltage Vt.

It is worth noting that generally, embodiments can be used for memory and other very large scale integration (VLSI) chip applications (e.g., logic). One non-limiting example is using aspects of the invention to provide a positive or negative voltage boost to the bit lines in a memory array.

FIG. 4 depicts the transient line voltage waveform (applied waveform 399); the pre-charge waveform (input waveform 397) as applied to the gate of the PFET in FIG. 2 and the gates of both the PFET and the FFET in FIG. 3; and the waveform 387, 387A of the virtual power rail 309 (floating line).

Note that the timing margin T_{M} may be, for example, 100 to 200 picoseconds, and will depend on the pulse width. As noted above, the boost δV, δV′ may be 0.1 V to 0.2 V above Vdd. “GND” refers to ground. FIG. 4 is applicable to the embodiment of FIG. 2 and the embodiment of FIG. 3. Note that δV and δV′ can be similar for FIG. 2 and FIG. 3 as this (0.1 V to 0.2 V) is the preferred boost which can be achieved through interconnect capacitance 391. The capacitance of the NFET 369 can be adjusted by reducing the size of it so that similar preferred boost is obtained in both embodiments. Again, note that the 0.1V-0.2V range is a non-limiting example and different embodiments can have different boosts.

FIG. 5 depicts a precursor structure 500 with a pre-charging circuit (represented by element 301) (such as from FIG. 2 or 3) and a device region 508 (e.g., a plurality of field effect transistors) at the front side of a substrate 502 (in the non-limiting example depicted, a silicon substrate), according to an illustrative embodiment. Note also the dielectric 509. The skilled artisan will be generally familiar with the fabrication of integrated circuits up to front end of line (FEOL) device fabrication as shown, and, given the teachings herein, can fabricate a precursor structure with a pre-charging circuit in the device layer (including 301 and 308).

FIG. 6 depicts the precursor structure 500 of FIG. 5 after formation of middle of line (MOL) contacts 599, and back end of line (BEOL) wiring 597 including power lines for VDD and VSS as shown. Note also the inter-layer dielectric (ILD) 595. The pre-charge circuit and device region 508 are connected to wiring 597 by contacts 599.

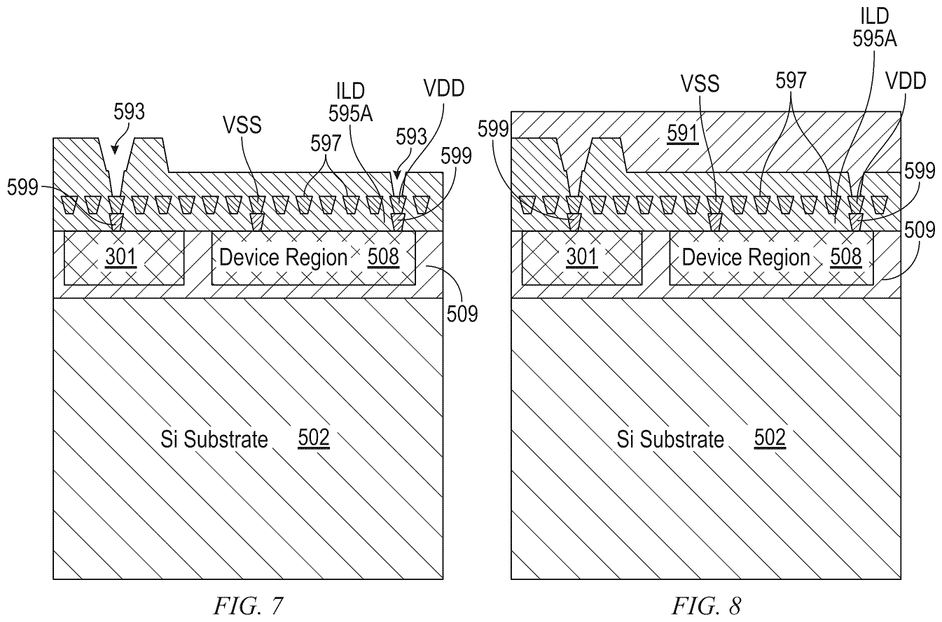

FIG. 7 depicts the structure of FIG. 6 after formation of additional via and metal line levels; note that M2 is used here for illustration but this exemplary structure applies to any metal layers: M1, M3, M4, . . . , Mx. With the additional ILD here, the ILD is designated as 595A. Note the cavities 593 for deposition of additional metal.

FIG. 8 depicts the structure of FIG. 7 after filling the cavities with metal 591 (in a non-limiting example, Ru).

FIG. 9 depicts the structure of FIG. 8 after subtractive patterning and etching to form first via bumps (teeth 589) over metal layer M2. The remaining metal 591 of FIG. 8 is designated as 591A in FIG. 9.

FIG. 10 depicts the structure of FIG. 9 after depositing additional ILD. The ILD after the additional deposition is referred to as 595B.

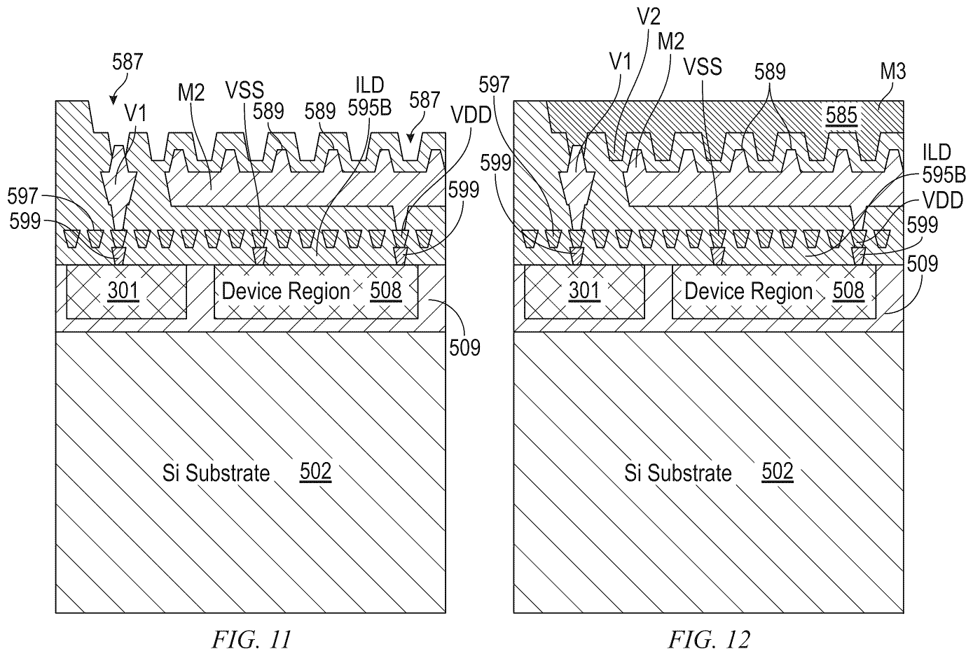

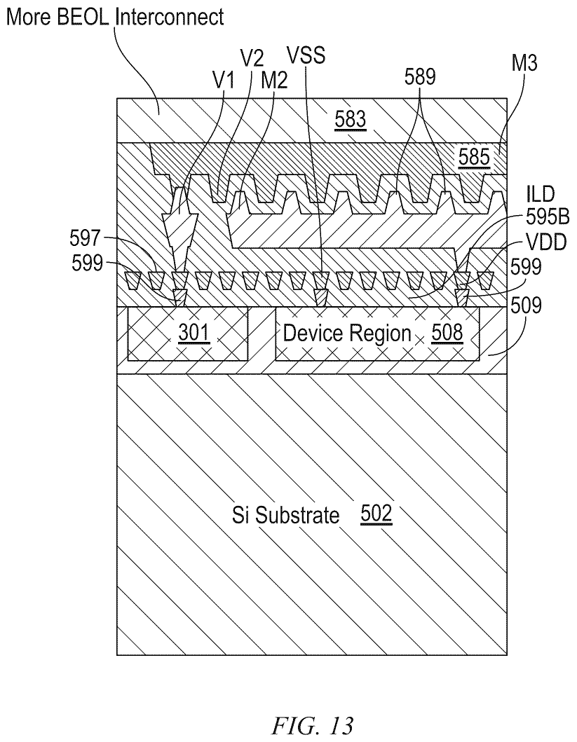

FIG. 11 depicts the structure of FIG. 10 after patterning for via layer V2 and metal layer M3. Note that metal layers are generally labeled as M1, M2, M3, . . . while via layers are generally labeled as V1 (between M1 and M2), V2 (between M2 and M3), V3 (between M3 and M4), . . . . Note the cavities 587 for deposition of additional metal. The cavities 587 should not be etched so deep as to reach the vias (teeth 589). A layer of ILD 595B should be maintained to isolate the downward vias from the upward vias as shown FIG. 12.

FIG. 12 depicts the structure of FIG. 11 after metallizing via layer V2 and metal layer M3 with additional metal to form virtual power rail 585.

FIG. 13 depicts the structure of FIG. 12 after forming additional BEOL interconnect layer(s) 583. Referring to FIG. 13 and also back to FIGS. 1-3, the pre-charging circuit can be realized, for example, as shown in FIG. 2 or FIG. 3. Via 313 in FIG. 1 is analogous to the contact 599 in FIG. 13 that connects to element 301 and then to the M1 layer and up to the virtual power rail. The M2 portion with upward-projecting vias (teeth 589) represents the transient line 305 connected to the device region 508 as shown while the M3 layer with downward-projecting vias represents the virtual power rail 309 (note the example in FIG. 1 shows formation at M1 and M2 instead of M2 and M3).

In view of the above discussion, it will be appreciated that in one aspect, an exemplary method includes providing/forming an FEOL circuit with device region and pre-charge circuit region (FIG. 5); forming MOL contacts and BEOL wires, where a power wire is connected to the device region (FIGS. 6-8); forming via bumps over the power wire (FIG. 9); and forming another metal wire with vias landing between the via bumps associated with the power wire, where the other metal wire is connected to the pre-charge circuit region (FIGS. 10-13).

Furthermore, in view of the above discussion, it will be appreciated that in another aspect, an exemplary semiconductor device includes a virtual power rail 309 and a transient line 305 coupled through separated via structures (e.g., the saw-like via structures 317-1, 317-2, 321-1, 321-2, 321-3 as shown). In the non-limiting example shown in FIG. 13, the virtual power rail is connected to a frontside pre-charging circuit. Embodiments can be used, for example, to positively or negatively boost the floating line for the functionality of the logic and memories connected to the transient power structure including the pre-charging circuit.

In addition to the process just described, an alternative process is possible which adds the benefit of forming the virtual functionality on the back side. Refer now to FIG. 14. Note the starting structure including substrate 1401, etch stop layer 1403, additional substrate material (e.g., Si) 1405, a device layer 1407 including a pre-charging circuit (or pre-discharging circuit), device region, and dielectric material (not separately shown or numbered but generally analogous to those discussed above); lower BEOL layers 1408 including metal lines and vias not separately numbered and ILD 1409; more BEOL layers 1411, and a carrier wafter 1413 formed over 1411.

FIG. 15 shows the structure of FIG. 14 after it is flipped.

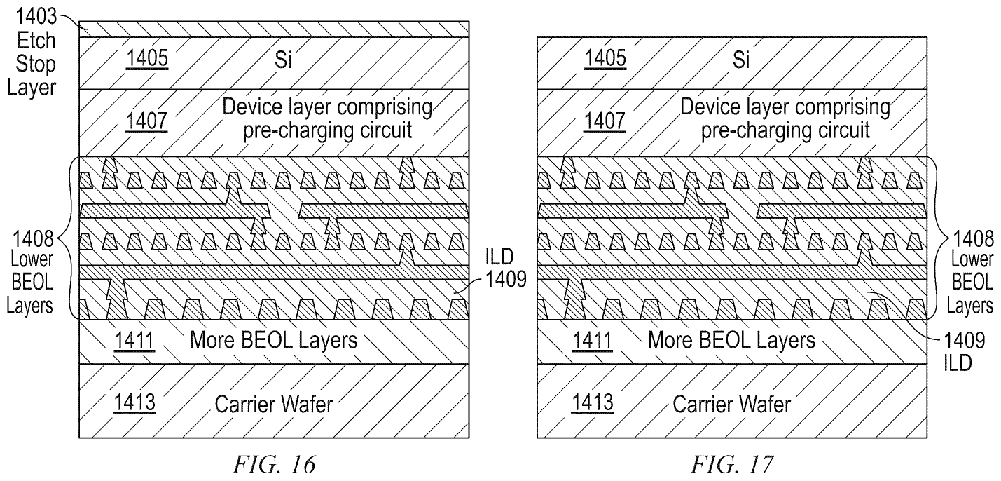

FIG. 16 shows the structure of FIG. 15 after substrate 1401 is removed, stopping on the etch stop layer 1403.

FIG. 17 shows the structure of FIG. 16 after etch stop layer 1403 is removed.

FIG. 18 shows the structure of FIG. 17 after removal of the remaining Si 1405 down to the device layer 1407.

FIG. 19 depicts the structure of FIG. 18 after formation of back side contacts 1415 and backside wiring layer BM1 1414 including power lines for VDD and VSS as shown. Note also the back side inter-layer dielectric (BILD) 1412. The pre-charge circuit and device region in the device layer 1407 are connected to the wiring by contacts 1415. In the non-limiting example of FIG. 19, the frontside BEOL (lower BEOL layers 1408) carries only signals and the back side BEOL formed in BILD 1412 carries only power.

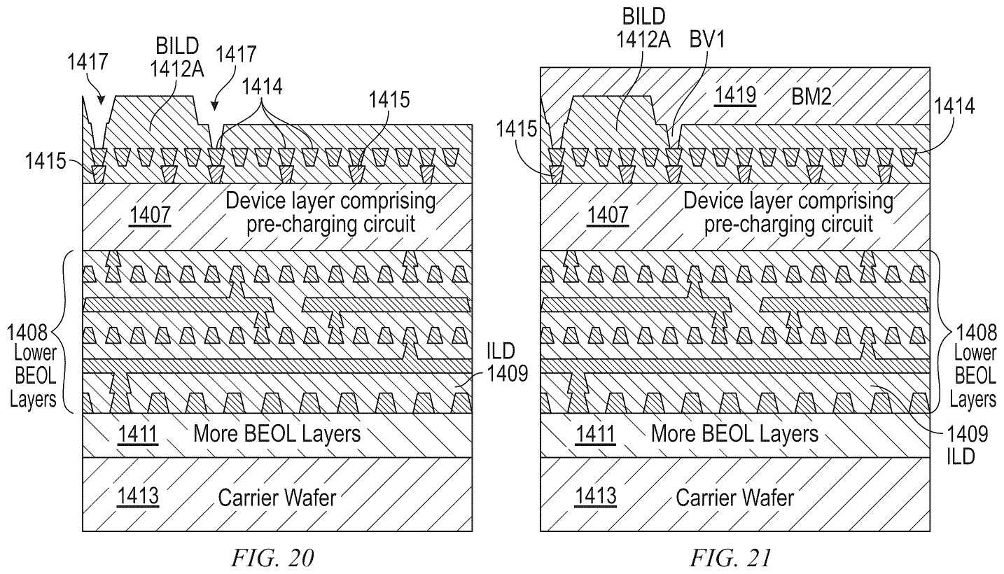

FIG. 20 depicts the structure of FIG. 19 after forming backside via layer BV1 and patterning for backside metal layer BM2 (generally, cavities 1417 into which metal for BV1 and BM2 will be deposited). Additional BILD is deposited and the BILD is now designated as 1412A. Note that back side BM2 is used here for illustration, but the exemplary structure applies to any backside layers: backside BM1, BM3, BM4, . . . , BMx.

FIG. 21 depicts the structure of FIG. 20 after metallizing the backside via layer BV1 and backside metal layer BM2 with a metal 1419 such as Ru.

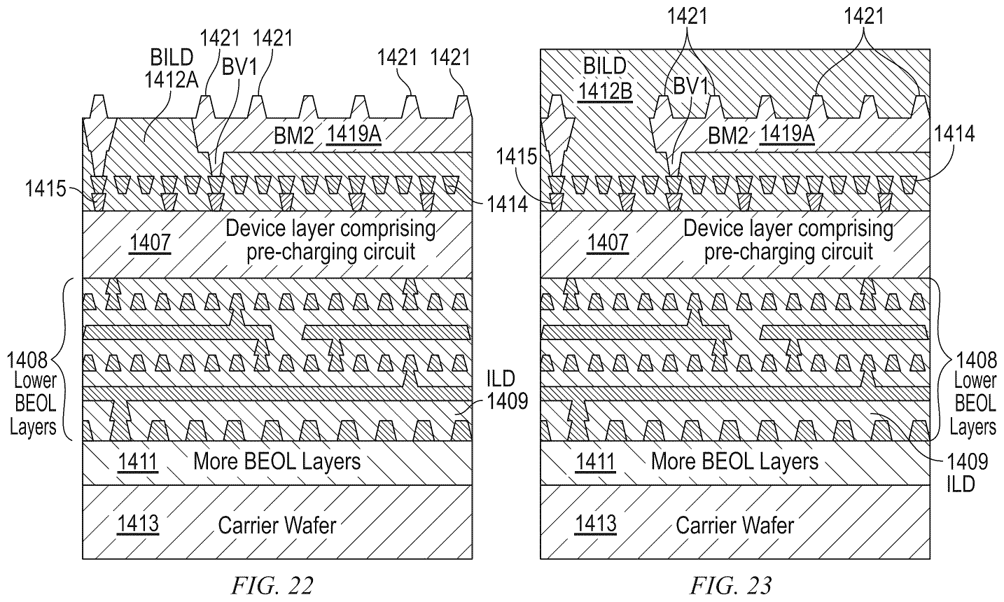

FIG. 22 depicts the structure of FIG. 21 after subtractive patterning and etching to form first back side via bumps (teeth 1421) over back side metal layer BM2. The remaining metal 1419 of FIG. 21 is designated as 1419A in FIG. 22.

FIG. 23 depicts the structure of FIG. 22 after depositing additional BILD. The BILD after the additional deposition is referred to as 1412B.

FIG. 24 depicts the structure of FIG. 23 after patterning for back side via layer BV2 and back side metal layer BM3. Note that back side metal layers are generally labeled as BM1, BM2, BM3, . . . while back side via layers are generally labeled as BV1 (between BM1 and BM2), BV2 (between BM2 and BM3), BV3 (between BM3 and BM4), . . . . Note the cavities 1423 for deposition of additional metal. The cavities 1423 should not be etched so deep as to reach the vias (teeth 1421). A layer of BILD 1412B should be maintained to isolate the downward vias from the upward vias as shown FIG. 24.

FIG. 25 depicts the structure of FIG. 24 after metallizing back side via layer BV2 and back side metal layer BM3 with additional metal to form the virtual power rail 1425.

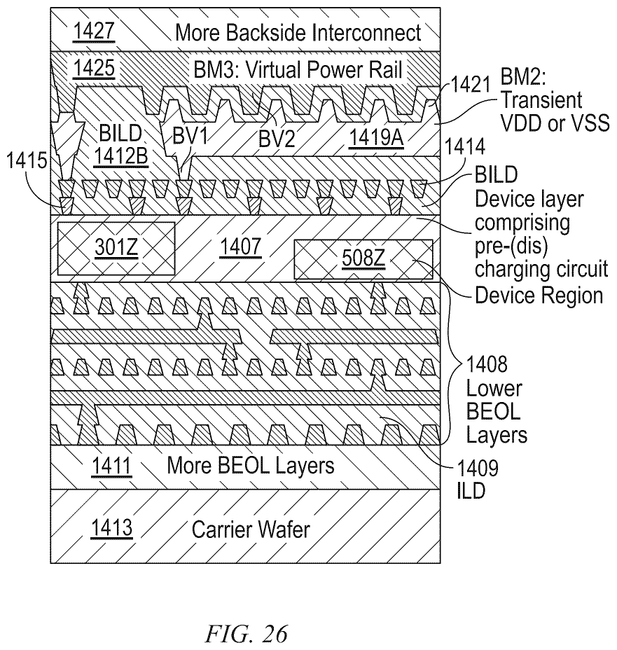

FIG. 26 depicts the structure of FIG. 25 after forming additional back side interconnect layer(s) 1427. Referring to FIG. 26 and also back to FIGS. 1-3, the pre-charging circuit can be realized, for example, as shown in FIG. 2 or FIG. 3. Via 313 in FIG. 1 is analogous to the contact 1415 in FIG. 26 that connects to the pre-charging circuit and then to the BM1 layer and up to the virtual power rail. The BM2 portion with upward-projecting vias (teeth 1421) represents the transient line 305 connected to the device region while the BM3 layer with downward-projecting vias represents the virtual power rail 309 (note the example in FIG. 1 shows formation at M1 and M2 instead of BM2 and BM3). Note that element 301Z is generally representative of both charging and pre-discharging circuits.

In view of the above discussion, it will be appreciated that in still another aspect, an exemplary method includes forming a backside transient power line in BMx-1 with a first via bump above (FIG. 22); forming a backside virtual power rail in BMx with a second via bump underneath (FIG. 25) with the first and second via bumps offset and separated by BILD. In this aspect, the backside virtual power rail is wired to a pre-(dis) charging circuit in device layer 1407 on the frontside of the wafer.

Furthermore, in view of the above discussion, it will be appreciated that in a further aspect, an exemplary semiconductor device includes a back side virtual power rail 309 and a backside transient line 305 coupled through separated via structures (e.g., the saw-like via structures 317-1, 317-2, 321-1, 321-2, 321-3 as shown). In the non-limiting example shown in FIG. 26, the backside virtual power rail is connected to a frontside pre-charging circuit in the device layer. Embodiments can be used, for example, to positively or negatively boost the floating line for the functionality of the logic and memories connected to the transient power structure including the pre-charging circuit. That is to say, generally, the structure shown in FIG. 1 connected to the circuit can be formed at the front side as in FIG. 13 or the back side as in FIG. 26.

Although as illustrated in the drawing Figures, the virtual power rail 309 is spaced vertically from the transient supply line 305, in other embodiments the virtual power rail and the transient supply line could be spaced horizontally from each other with horizontally interdigitated projections separated by dielectric.

Furthermore, it is worth noting that the examples in the figures typically depict interdigitation. However, generally, it is possible, for example, to interdigitate or to provide long continuous lines next to virtual lines for coupling, without interdigitation.

Given the teachings herein, for any elements for which example materials are not set forth, the skilled artisan can select appropriate materials, and for any fabrication steps for which specific exemplary processes have not been set forth, the skilled artisan can select appropriate known processes. Exemplary known processes, in no particular order, include, for example, preparation (deposition/patterning) of nanosheet stacks with sacrificial SiGe regions, etch-back of sacrificial SiGe, formation of shallow trench isolation (STI), dummy gates including gate spacers, inner spacers, and BDI, dummy gate open, dummy gate removal, channel release, HKMG stack deposition, self-aligned contact (SAC) cap and trench metal contact formation, and with lithography, masks, and patterning, generally. The skilled artisan will be familiar with the “dummy gate” process for forming HKMGs. More generally, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. These processes could be used, for example, to form FETs in the pre-charge circuits and/or the device regions.

Bulk silicon is a non-limiting example of a suitable substrate material, other materials are also possible.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present technology can be employed in essentially any application and/or electronic system. Given the teachings of the present disclosure provided herein, one of ordinary skill in the art will be able to contemplate other implementations and applications of embodiments disclosed herein.

Computer System that could Use Circuits in Accordance with Aspects of the Invention and/or Control Processes Used in Semiconductor Design, Manufacture, and/or Test

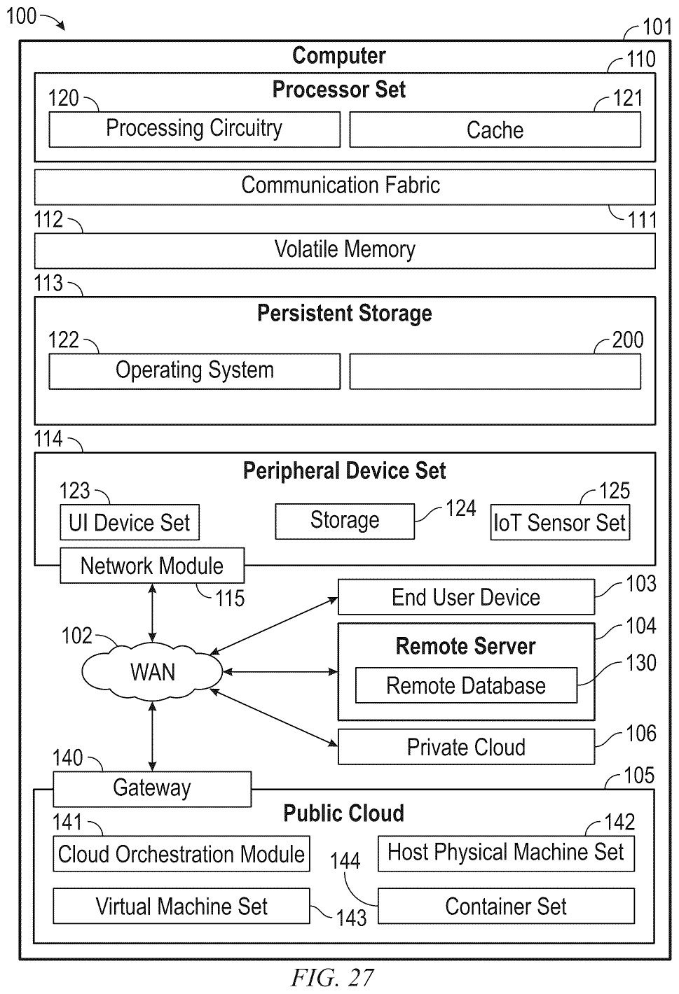

Refer now to FIG. 27.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as an electronic design automation tool 200 as discussed below with respect to FIG. 28. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 27. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 28 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 28 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a device layer including a device region with a plurality of devices and a pre-charging circuit;
a front side wiring layer, located on a front side of the device layer, and including at least signal wiring connected to the device region;
a supply voltage line coupled to the device region; and
a back side wiring layer, located on a back side of the device layer, and including:
a virtual power rail coupled to the pre-charging circuit;
a transient line capacitively but not conductively coupled to the virtual power rail and coupled to the device region;
wherein the pre-charging circuit is configured to cause the virtual power rail to experience a voltage differential from a supply voltage applied to the supply voltage line responsive to a pulse on the transient line.

2. The semiconductor structure of claim 1, wherein the virtual power rail and the transient line are formed with interdigitated conductive teeth separated by a dielectric.

3. The semiconductor structure of claim 2, wherein the virtual power rail and the transient line are vertically spaced from each other and the interdigitated conductive teeth comprise vertical vias.

4. The semiconductor structure of claim 3, wherein the pre-charging circuit comprises a p-type field effect transistor having a first drain-source terminal coupled to the supply voltage line, a gate, and a second drain-source terminal coupled to the virtual power rail.

5. The semiconductor structure of claim 4, further comprising a controller and power supply configured to supply input pulse waveforms to the transient supply line and the gate of the p-type field effect transistor.

6. The semiconductor structure of claim 5, wherein the input pulse waveforms are in phase and the voltage differential is positive.

7. The semiconductor structure of claim 5, wherein the input pulse waveforms are out of phase and the voltage differential is negative.

8. The semiconductor structure of claim 3, wherein the pre-charging circuit comprises:
a p-type field effect transistor having a first drain-source terminal coupled to the supply voltage line, a gate, and a second drain-source terminal coupled to the virtual power rail; and
an n-type field effect transistor having a first drain-source terminal coupled to the first drain-source terminal of the p-type field effect transistor, a gate coupled to the gate of the p-type field effect transistor, and a second drain-source terminal coupled to the second drain-source terminal of the p-type field effect transistor.

9. The semiconductor structure of claim 8, further comprising a controller and power supply configured to supply input pulse waveforms to the transient supply line and the gates of the p-type field effect transistor and the n-type field effect transistor.

10. The semiconductor structure of claim 9, wherein the input pulse waveforms are in phase and the voltage differential is positive.

11. The semiconductor structure of claim 9, wherein the input pulse waveforms are out of phase and the voltage differential is negative.

12. A semiconductor structure comprising:
a device layer including a device region with a plurality of devices and a pre-charging circuit;
a supply voltage line coupled to the device region; and
a wiring layer, located adjacent the device layer, and including:
a virtual power rail coupled to the pre-charging circuit; and
a transient line capacitively but not conductively coupled to the virtual power rail and coupled to the device region;
wherein:
the pre-charging circuit is configured to cause the virtual power rail to experience a voltage differential from a supply voltage applied to the supply voltage line responsive to a pulse on the transient line; and
the virtual power rail and the transient line are formed with interdigitated conductive teeth separated by a dielectric.

13. The semiconductor structure of claim 12, wherein the virtual power rail and the transient line are vertically spaced from each other and the interdigitated conductive teeth comprise vertical vias.

14. The semiconductor structure of claim 13, wherein the pre-charging circuit comprises a p-type field effect transistor having a first drain-source terminal coupled to the supply voltage line, a gate, and a second drain-source terminal coupled to the virtual power rail.

15. The semiconductor structure of claim 14, further comprising a controller and power supply configured to supply input pulse waveforms to the transient supply line and the gate of the p-type field effect transistor.

16. The semiconductor structure of claim 15, wherein the input pulse waveforms are in phase and the voltage differential is positive.

17. The semiconductor structure of claim 15, wherein the input pulse waveforms are out of phase and the voltage differential is negative.

18. The semiconductor structure of claim 13, wherein the pre-charging circuit comprises:
a p-type field effect transistor having a first drain-source terminal coupled to the supply voltage line, a gate, and a second drain-source terminal coupled to the virtual power rail; and
an n-type field effect transistor having a first drain-source terminal coupled to the first drain-source terminal of the p-type field effect transistor, a gate coupled to the gate of the p-type field effect transistor, and a second drain-source terminal coupled to the second drain-source terminal of the p-type field effect transistor.

19. The semiconductor structure of claim 18, further comprising a controller and power supply configured to supply input pulse waveforms to the transient supply line and the gates of the p-type field effect transistor and the n-type field effect transistor.

20. The semiconductor structure of claim 19, wherein the input pulse waveforms are in phase and the voltage differential is positive.

21. The semiconductor structure of claim 19, wherein the input pulse waveforms are out of phase and the voltage differential is negative.

22. A semiconductor structure comprising:
a device layer including a device region with a plurality of devices and a pre-discharging circuit;
a front side wiring layer, located on a front side of the device layer, and including at least signal wiring connected to the device region;
a back side wiring layer, located on a back side of the device layer, and including:
a virtual power rail coupled to the pre-discharging circuit; and
a transient line capacitively but not conductively coupled to the virtual power rail and coupled to the device region;
wherein the pre-discharging circuit is configured to cause the virtual power rail to experience a voltage differential from an initial ground potential responsive to a pulse on the transient line.

23. The semiconductor structure of claim 22, wherein the virtual power rail and the transient line are formed with interdigitated conductive teeth separated by a dielectric.

24. A semiconductor structure comprising:
a device layer including a device region with a plurality of devices and a pre-discharging circuit; and
a wiring layer, located adjacent the device layer, and including:
a virtual power rail coupled to the pre-discharging circuit; and
a transient line capacitively but not conductively coupled to the virtual power rail and coupled to the device region;
wherein:
the pre-discharging circuit is configured to cause the virtual power rail to experience a voltage differential from an initial ground potential responsive to a pulse on the transient line; and
the virtual power rail and the transient line are formed with interdigitated conductive teeth separated by a dielectric.

25. A method of forming a semiconductor structure, the method comprising:
providing an initial structure including a carrier wafer, a plurality of front side wiring layers outward of the carrier wafer, and a device layer outward of the plurality of front side wiring layers, the device layer including a device region and a pre-charging circuit;
forming a back side transient power line on a back side of the device region, the back side transient power line including wiring in a first metal region with first via bumps extending therefrom;
forming a back side virtual power rail on the back side of the device region, the back side virtual power rail including wiring in a second metal region that is spaced vertically from the first metal region, the back side virtual power rail further including second via bumps extending therefrom, the first via bumps and the second via bumps extending towards each other and being interdigitated and separated from each other by back side inter layer dielectric, the back side virtual power rail being coupled to the pre-charging circuit.
